(19) United States
(12) Patent Application Publication
(10) Pub. No.: US 2013/0169351 A1
(43) Pub. Date: Jul. 4, 2013

(54) TRANSISTOR OPERATING METHOD

(71) Applicants: Ting-Chang CHANG, Kaohsiung City (TW); Te-Chih Chen, Pingtung County (TW); Fu-Yen Jian, Kaohsiung City (TW); Tien-Yu Hsieh, Taichung City (TW)

(72) Inventors: Ting-Chang CHANG, Kaohsiung City (TW); Te-Chih Chen, Pingtung County (TW); Fu-Yen Jian, Kaohsiung City (TW); Tien-Yu Hsieh, Taichung City (TW)

(21) Appl. No.: 13/416,594

(22) Filed: Mar. 9, 2012

(30) Foreign Application Priority Data
Jan. 3, 2012 (TW) 101100157

(51) Int. Cl. G11C 5/14

(52) U.S. Cl. 327/530

(57) ABSTRACT

A transistor operating method is applicable to a transistor including a first gate, a first gate insulating layer, a semiconductor layer, a source, a drain, a second gate insulating layer and a second gate. The transistor operating method includes: grounding the first gate and the source, applying a negative bias to the second gate and applying a positive bias to the drain, so that the transistor acts as an optical detector; alternatively, grounding the source, grounding or floating the second gate, applying a bias to the first gate and applying a positive bias to the drain, so that the transistor acts as a pixel switch.

### CROSS-REFERENCE TO RELATED APPLICATION

This application claims the benefit of Taiwan Patent Application No. 101100157, filed on Jan. 3, 2012, which is hereby incorporated by reference for all purposes as if fully set forth herein.

### BACKGROUND

1. Field of Disclosure

The present disclosure relates to an operating method, and more particularly to a transistor operating method.

2. Related Art

A touch panel is generally used in a smart phone, a tablet computer, an industrial computer and a commercial computer, and has high production value and is greatly demanded in the market. The conventional touch panel technologies may be classified, according to the working principle of the sensor and the signal transmission mode, into a capacitor type, a resistor type, an infrared type and an acoustic type. The above-mentioned touch panels all need to be equipped with an additional touch object on a conventional display, which reduces the light transmittance of the display and increases the reflection of the external light, and the added touch object also increases the cost of the touch display.

If a touch screen is formed on the panel by using an optical detector, the reflection of the external light is reduced, and the fabrication cost is lowered. However, the optical detector may affect an aperture ratio of pixels, and the light transmittance of the display is still not effectively improved. When an ordinary thin-film transistor (TFT) is used to control the gray level of the pixels, a light shading method (using a black matrix) or a method of reducing illumination sensitivity (for example, using a transparent TFT) needs to be adopted to reduce the impact of the light. Therefore, an ordinary TFT cannot act as an optical detector and a pixel switch at the same time, and an optical detector needs to be fabricated individually on the panel when a touch screen is formed, which may affect the aperture ratio of the pixels and increase the fabrication cost.

### SUMMARY

An embodiment of the present disclosure provides a transistor operating method, which acts as an optical detector and a pixel switch at the same time.

An embodiment of the present disclosure provides a transistor operating method, applicable to a transistor including a first gate, a first gate insulating layer, a semiconductor layer, a source, a drain, a second gate insulating layer and a second gate. The first gate insulating layer is disposed on the first gate, the semiconductor layer is disposed on the first gate insulating layer, the source and the drain are separately disposed on two sides of the semiconductor layer, the second gate insulating layer is disposed on the semiconductor layer, and the second gate is disposed on the second gate insulating layer. The transistor operating method includes: grounding the first gate and the source, applying a negative bias to the second gate and applying a positive bias to the drain, so that the transistor acts as an optical detector.

Alternatively, an embodiment of the present disclosure provides another transistor operating method, which includes: grounding the source, grounding or floating the second gate, applying a bias to the first gate and applying a positive bias to the drain, so that the transistor acts as a pixel switch.

The feature of the embodiment of the present disclosure lies in that, the transistor having two gates may act as the pixel switch and the optical detector at the same time; and meanwhile, the transistor may also act as a touch element due to its optical sensitivity.

### BRIEF DESCRIPTION OF THE DRAWINGS

The present disclosure will become more fully understood from the detailed description given herein below for illustration only, and thus are not limitative of the present disclosure, and wherein:

FIG. 1 is a schematic structural diagram of a transistor in a transistor operating method according to an embodiment of the present disclosure;

FIG. 2A is a flow chart of a transistor operating method according to an embodiment of the present disclosure;

FIG. 2B is a flow chart of a transistor operating method according to another embodiment of the present disclosure;

FIG. 3 is a schematic electrical diagram of the operation of a second gate in FIG. 1 acting as a control gate in an illumination and a dark state environment;

FIG. 4 is a schematic electrical diagram of the operation of a first gate in FIG. 1 acting as a control gate in an illumination and a dark state environment;

FIG. 5 is a schematic energy band diagram of the operation of the second gate in FIG. 1 acting as a control gate in an illumination and a dark state environment;

FIG. 6 is a schematic energy band diagram of the operation of the first gate in FIG. 1 acting as a control gate in an illumination and a dark state environment; and

FIG. 7 is a spectrogram of a light source applied in the transistor operating method according to an embodiment of the present disclosure.

### DETAILED DESCRIPTION

To make the characteristic of the present disclosure comprehensible, embodiments of the present disclosure are illustrated in detail below with the accompanying drawings.

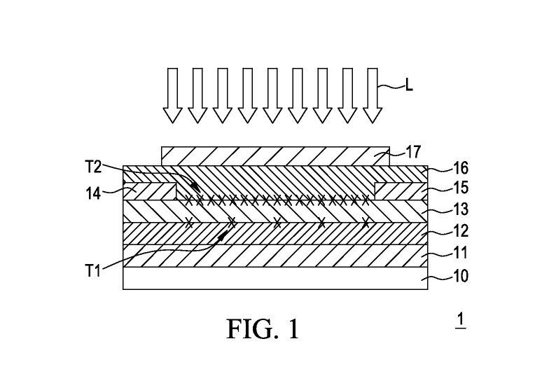

FIG. 1 is a schematic structural diagram of a transistor in a transistor operating method according to an embodiment of the present disclosure.

Referring to FIG. 1, the transistor 1 includes a first gate 11, a first gate insulating layer 12, a semiconductor layer 13, a source 14, a drain 15, a second gate insulating layer 16 and a second gate 17.

Specifically, the first gate insulating layer 12 is disposed on the first gate 11, the semiconductor layer 13 is disposed on the first gate insulating layer 12, the source 14 and the drain 15 are separately disposed on two sides of the semiconductor layer 13, the second gate insulating layer 16 is disposed on the semiconductor layer 13, and the second gate 17 is disposed on the second gate insulating layer 16.

Preferably, the first gate 11 is a metal gate. The first gate 11 is further used for controlling the conductivity of the semiconductor layer 13. The first gate insulating layer 12 is used for isolating the contact between the first gate 11 and the semiconductor layer 13, the source 14 and the drain 15. The first gate insulating layer 12 includes SiO₂ or SiN₄.

The semiconductor layer 13 includes a metal oxide, and the metal oxide may be, and is not limited to, ZnO, IGZO, ZTO, IZO or ZITO. The second gate insulating layer 16 is used for isolating the contact between the second gate 17 and the semiconductor layer 13, the source 14 and the drain 15. The second gate insulating layer 16 further includes SiO₂ or SiN₄. The second gate 17 is further used for controlling the conductivity of the semiconductor layer 13. Preferably, the second gate 17 is a transparent gate including ITO.

It can be seen from the structure of the transistor 1, which a first channel T1 for light L to pass through is further provided between the semiconductor layer 13 and the first gate insulating layer 12; and likewise, a second channel T2 for light L to pass through is also provided between the semiconductor layer 13 and the second gate insulating layer 16.

It should be noted that, the structure of the transistor 1 is for illustration only, that is, the sequence of the layers in the structure of the transistor 1 is exchangeable, and is not limited to the configuration described above or shown in FIG. 1. For example, the first gate 11 and the second gate 17 may respectively act as a lower gate and an upper gate of the transistor 1; alternatively, the first gate 11 and the second gate 17 may respectively act as an upper gate and a lower gate of the transistor 1.

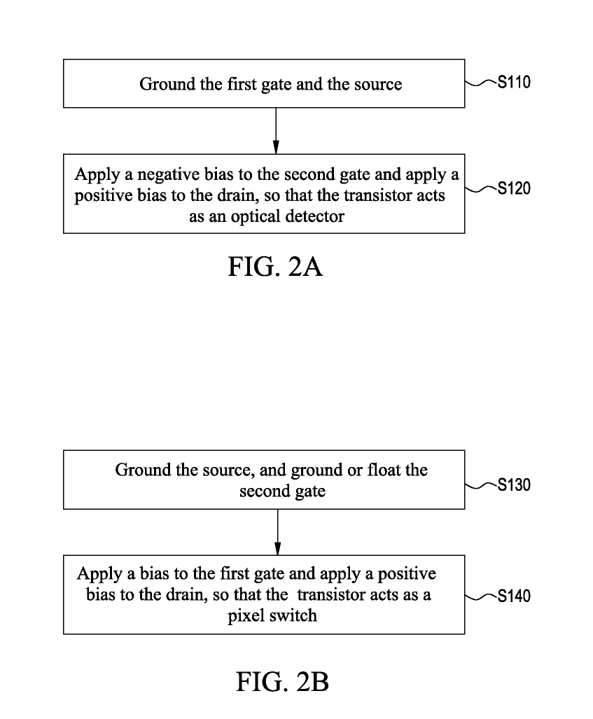

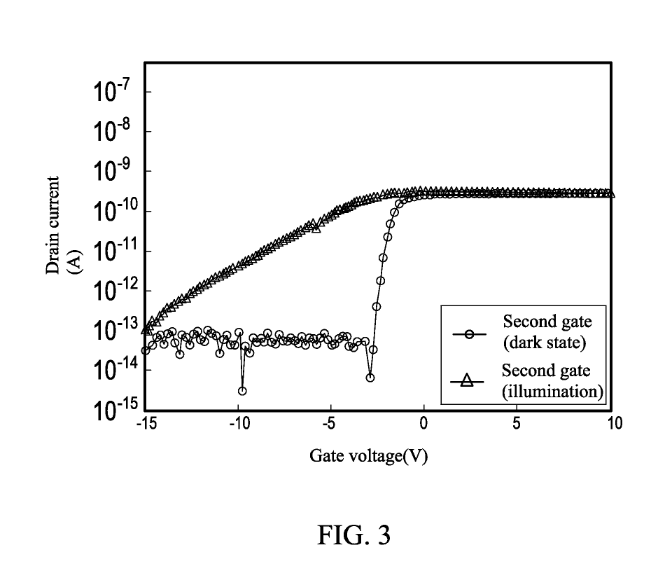

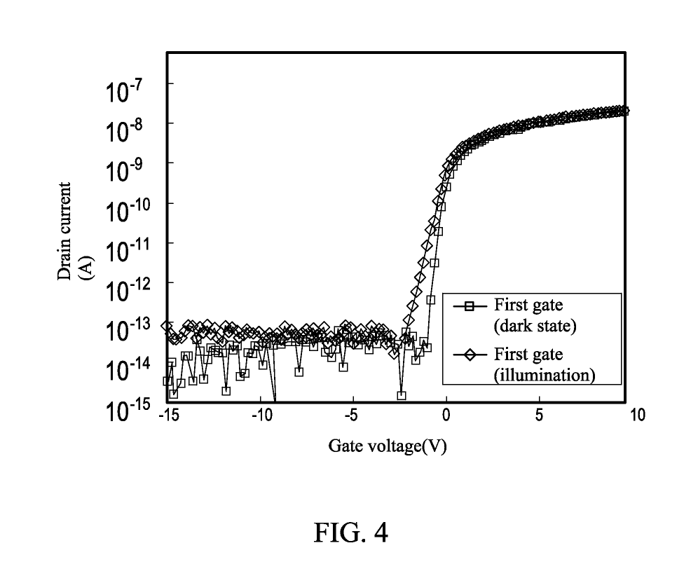

Referring to FIG. 1, FIG. 2A, FIG. 2B, FIG. 3 and FIG. 4, FIG. 2A is a flow chart of a transistor operating method according to an embodiment of the present disclosure, FIG. 2B is a flow chart of a transistor operating method according to another embodiment of the present disclosure, FIG. 3 is a schematic electrical diagram of the operation of the second gate in FIG. 1 acting as a control gate in an illumination and a dark state environment, and FIG. 4 is a schematic electrical diagram of the operation of the first gate in FIG. 1 acting as a control gate in an illumination and a dark state environment.

Referring to FIG. 2A, the transistor operating method includes: grounding the first gate and the source (Step S110); and applying a negative bias to the second gate and applying a positive bias to the drain, so that the transistor acts as an optical detector (Step S120).

Alternatively, referring to FIG. 2B, the transistor operating method includes: grounding the source, and grounding or floating the second gate (Step S130); and applying a bias to the first gate and applying a positive bias to the drain, so that the transistor acts as a pixel switch (Step S140).

The two operating methods in Step S110 to Step S120 (the transistor acting as the optical detector) and in Step S130 to Step S140 (the transistor acting as the pixel switch) can be used alternatively according to actual requirements. For example, the transistor may act as the optical detector, or the transistor may act as the pixel switch. The floating means not being connected to any signal source, which is comprehensible to those skilled in the art and will not be described herein again.

Specifically, referring to FIG. 1 and FIG. 3, in Step S110 and Step S120, a positive bias (for example, 0.1 V) is applied to the drain 15, and the source 14 is grounded (for example, 0 V).

If the second gate 17 (a transparent gate including ITO) acts as a control gate (for example, a voltage of −15 V to +15 V is applied), the first gate 11 is 0 V. Preferably, when a negative bias is applied to the second gate 17, an apparent optical current is generated in the illumination environment, and in this case, the transistor 1 can be used as the optical detector. Due to the difference of the optical sensitivity, a shading object (for example, a finger or touch pen) may be used to block the light source L (for example, external incident light), or an object reflects a back light source to generate an optical signal difference, so that the transistor 1 may act as a touch element by reading the difference of current signals.

Alternatively, referring to FIG. 1 and FIG. 4, in Step S130 and Step S140, a positive bias (for example, 0.1 V) is applied to the drain 15, and the source 14 is grounded (for example, 0 V).

If the first gate 11 acts as a control gate (for example, a voltage of −15 V to +15 V is applied), the second gate 17 is 0 V or floated. In this embodiment, when a negative or a positive bias is applied to the first gate 11, no matter in the illumination or the dark state environment, the transistor 1 is turned on or off, and may act as a pixel switch on the display.

Thereby, due to the difference of interface features under the control of different gates (for example, the first gate and the second gate), different optical sensitivities are obtained. The transistor may act as a pixel switch in a gate control area with a low optical sensitivity, and may act as an optical detector element in a gate control area with a high optical sensitivity.

However, the above parameter conditions are only for reference to facilitate comprehension of the operating mode and the principle of the transistor 1 acting as the optical detector, the touch element or the pixel switch, and the present disclosure is not limited thereto. In practice, an operator may apply different working conditions (for example, different voltage ranges or time conditions) on the transistor 1 according to actual requirements.

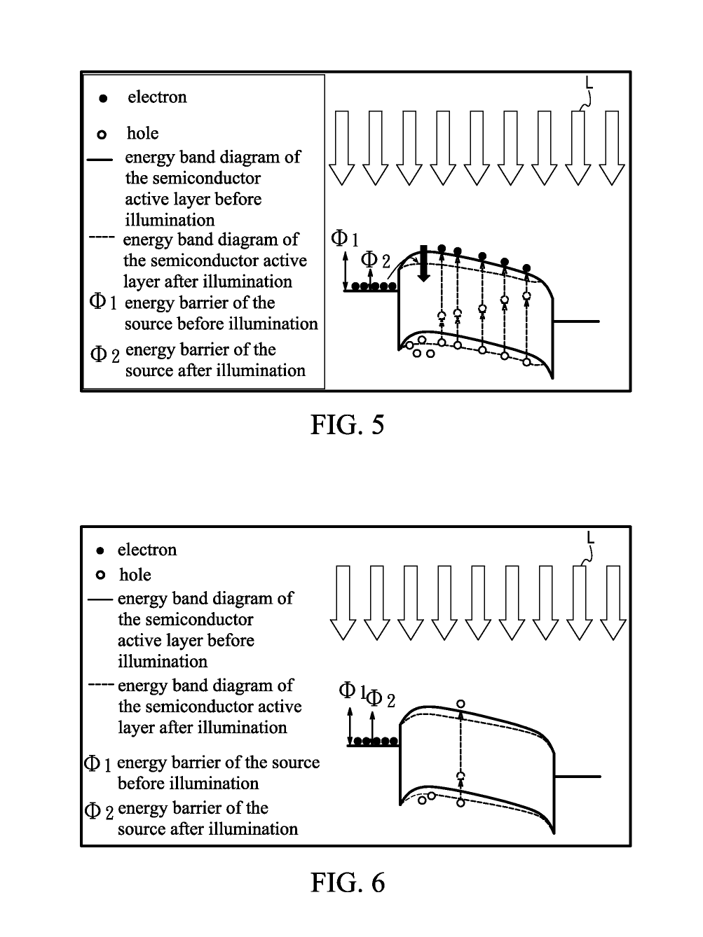

Referring to FIG. 1, FIG. 5 and FIG. 6, FIG. 5 is a schematic energy band diagram of the operation of the second gate in FIG. 1 acting as a control gate in an illumination and a dark state environment, and FIG. 6 is a schematic energy band diagram of the operation of the first gate in FIG. 1 acting as a control gate in an illumination and a dark state environment.

Referring to FIG. 1 and FIG. 5, when the light L (for example, the external light) is incident to the second channel T2 controlled by the second gate (for example, a back channel area), since an interface of the second channel T2 has many traps, a mass of trap assisted photogenerated electron-hole pairs is generated when the second channel T2 is illuminated, and the holes are pushed to the source 14 under the positive voltage of the drain 15, thereby reducing the energy barrier of the source 14 and generating a mass of photo leakage current. Due to the optical sensitivity of the second channel T2 in operation, the transistor 1 may act as an optical detector, and due to the difference of the current in the illumination and the dark state environment, it is judged whether the external incident light is shaded (for example, shaded by a finger or touch pen), or an object reflects a back light source to generate an optical signal difference, so that the transistor 1 may act as a touch element by using the operating principle.

Referring to FIG. 1 and FIG. 6, if the first gate 11 acts as the first channel T1 of the control gate (for example, a front channel area), since the number of the traps is small, photogenerated electron-hole pairs may not be easily generated in the illumination environment, and the sensitivity to the illumination is not apparent.

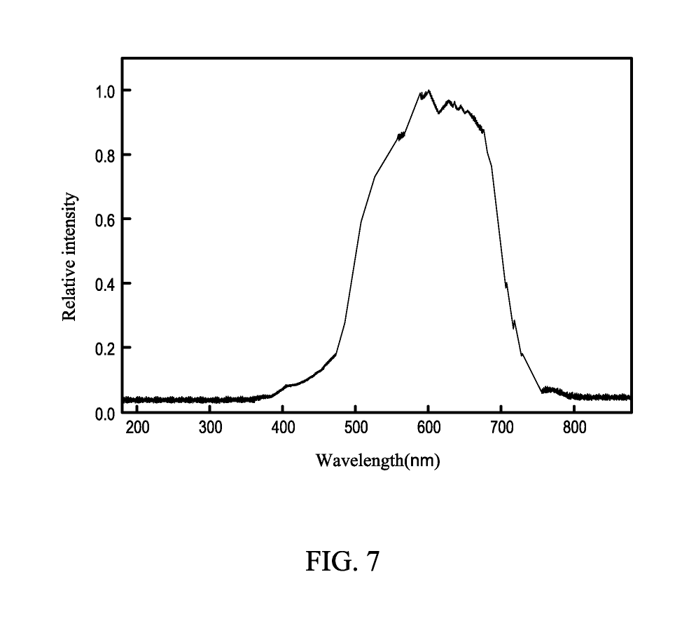

FIG. 7 is a spectrogram of a light source applied in the transistor operating method according to an embodiment of the present disclosure.

In view of the above, the light L (as shown in FIG. 3 to FIG. 6) is visible light, and the wavelength and the relative intensity of the light L are shown in FIG. 7 (for example, the wavelength of the light source is approximately 400 nm to 700 nm; and the intensity of the light source is 10000 lux). Further, in the above description, the metal oxide of the semiconductor active layer 13 is, for example, IGZO. However, these conditions are merely for reference to facilitate illustration, and the present disclosure is not limited thereto.

In view of the above, if the first gate 11 and the second gate 17 have different optical sensitivities, the transistor 1 may act as the optical detector or the pixel transistor (pixel switch).

It should be noted that, due to the difference of the optical sensitivities, the first gate 11 and the second gate 17 are exchangeable. For example, the first gate 11 and the second gate 17 may respectively act as the pixel switch and the optical detector; alternatively, the first gate 11 and the second gate 17 may respectively act as the optical detector and the pixel transistor (pixel switch), and in this case, the operating conditions of the first gate 11 and the second gate 17 need to be exchanged accordingly.

Therefore, the transistor operating method according to the embodiment of the present disclosure has the following features.

1. Through the operation of different gates (for example, the first gate and the second gate), the transistor may act as a pixel switch or an optical detector.

2. Due to its optical sensitivity, the transistor may act as a touch element.

3. To effectively improve the aperture ratio of the pixels and greatly reduce the fabrication cost of the touch panel, the transistor can be directly applied in the current semiconductor and photoelectric industries.

The disclosure being thus described, it will be obvious that the same may be varied in many ways. Such variations are not to be regarded as a departure from the spirit and scope of the disclosure, and all such modifications as would be obvious to one skilled in the art are intended to be included within the scope of the following claims.

What is claimed is:

1. A transistor operating method, applicable to a transistor comprising a first gate, a first gate insulating layer, a semiconductor layer, a source, a drain, a second gate insulating layer and a second gate, wherein the first gate insulating layer is disposed on the first gate, the semiconductor layer is disposed on the first gate insulating layer, the source and the drain are separately disposed on two sides of the semiconductor layer, the second gate insulating layer is disposed on the semiconductor layer, and the second gate is disposed on the second gate insulating layer, the transistor operating method comprising:
grounding the first gate and the source; and
applying a negative bias to the second gate and applying a positive bias to the drain, so that the transistor acts as an optical detector.

2. The transistor operating method according to claim 1, wherein the first gate insulating layer isolates the contact between the first gate and the semiconductor layer, the source and the drain.

3. The transistor operating method according to claim 1, wherein the semiconductor layer comprises a metal oxide.

4. The transistor operating method according to claim 3, wherein the metal oxide comprises ZnO, IGZO, ZTO, IZO or ZITO.

5. The transistor operating method according to claim 1, wherein the second gate insulating layer isolates the contact between the second gate and the semiconductor layer, the source and the drain.

6. The transistor operating method according to claim 1, wherein the second gate is a transparent gate comprising ITO.

7. The transistor operating method according to claim 1, wherein the second gate comprising ITO.

8. A transistor operating method, applicable to a transistor comprising a first gate, a first gate insulating layer, a semiconductor layer, a source, a drain, a second gate insulating layer and a second gate, wherein the first gate insulating layer is disposed on the first gate, the semiconductor layer is disposed on the first gate insulating layer, the source and the drain are separately disposed on two sides of the semiconductor layer, the second gate insulating layer is disposed on the semiconductor layer, and the second gate is disposed on the second gate insulating layer, the transistor operating method comprising:
grounding the source, and grounding or floating the second gate; and
applying a bias to the first gate and applying a positive bias to the drain, so that the transistor acts as a pixel switch.

9. The transistor operating method according to claim 8, wherein the first gate insulating layer isolates the contact between the first gate and the semiconductor layer, the source and the drain.

10. The transistor operating method according to claim 8, wherein the semiconductor layer comprises a metal oxide.

11. The transistor operating method according to claim 10, wherein the metal oxide comprises ZnO, IGZO, ZTO, IZO or ZITO.

12. The transistor operating method according to claim 8, wherein the second gate insulating layer isolates the contact between the second gate and the semiconductor layer, the source and the drain.

13. The transistor operating method according to claim 8, wherein the second gate is a transparent gate.

14. The transistor operating method according to claim 8, wherein the second gate comprising ITO.
